(19) United States
(12) Patent Application Publication
(10) Pub. No.: US 2025/0204072 A1
(43) Pub. Date: Jun. 19, 2025

(54) IMAGE SENSOR AND METHOD OF FABRICATING THE SAME

(71) Applicant: SAMSUNG ELECTRONICS CO., LTD., Suwon-si (KR)

(72) Inventor: Kook Tae Kim, Suwon-si (KR)

(21) Appl. No.: 18/795,874

(22) Filed: Aug. 6, 2024

(30) Foreign Application Priority Data
Dec. 15, 2023 (KR) 10-2023-0183087

(51) Int. Cl. H01L 27/146

(52) U.S. Cl. CPC H10F 39/807; H10F 39/011; H10F 39/182; H10F 39/80373; H10F 39/805; H10F 39/8053; H10F 39/8063

(57) ABSTRACT

An example image sensor includes a substrate, a deep isolation pattern, and a shallow device isolation pattern. The substrate has first and second surfaces and includes a plurality of pixel regions. The deep isolation pattern extends from the first surface into the substrate and interposed between the plurality of pixel regions. The shallow device isolation pattern extends from the first surface into the substrate, where the deep isolation pattern and the shallow device isolation pattern are spaced apart from each other, a width of the deep isolation pattern is constant, and a width of the shallow device isolation pattern decreases as a distance from the first surface increases.

### CROSS-REFERENCE TO RELATED APPLICATION

This application claims priority under 35 U.S.C. § 119 to Korean Patent Application No. 10-2023-0183087 filed on Dec. 15, 2023, in the Korean Intellectual Property Office, the entire contents of which are hereby incorporated by reference.

### BACKGROUND

An image sensor is a semiconductor device that converts optical images into electrical signals. As the computer and communications industries have developed, demand has increased for high-performance image sensors in a variety of applications, including digital cameras, camcorders, personal communication systems, gaming machines, security cameras, and micro-cameras for medical applications. Image sensors may be categorized as any one of charge coupled device (CCD) image sensors and CMOS image sensors (CIS). A CIS typically includes a plurality of two-dimensionally arranged pixels. Each of the pixels may include a photodiode that converts incident light into an electrical signal. The plurality of pixels are defined by a deep isolation pattern disposed therebetween. A plurality of devices of one pixel are separated by a device isolation pattern.

### SUMMARY

The present disclosure relates to an image sensor that is advantageous for pixel miniaturization, an image sensor with improved sensitivity, an image sensor that is capable of being easily integrated, and methods of fabricating the same.

In general, according to some aspects, an image sensor may include a substrate having first and second surfaces facing each other and including a plurality of pixel regions, a deep isolation pattern extending from the first surface into the substrate and interposed between the plurality of pixel regions, and a shallow device isolation pattern extending from the first surface into the substrate, the deep isolation pattern and the shallow device isolation pattern may be spaced apart from each other, a width of the deep isolation pattern may be constant, and a width of the shallow device isolation pattern may decrease as a distance from the first surface increases.

In general, according to some aspects, an image sensor may include a substrate having first and second surfaces facing each other and including a plurality of pixel regions, a deep isolation pattern extending from the first surface into the substrate and interposed between the plurality of pixel regions, and a shallow device isolation pattern extending from the first surface into the substrate, the deep isolation pattern may include a buried insulating pattern in contact with the first surface, an intervening insulating pattern on the buried insulating pattern, a buried layer on the intervening insulating pattern, a conductive liner on the buried layer, an insulating liner on the conductive liner, and a doped region on the insulating liner, and the intervening insulating pattern may surround side and upper surfaces of the buried insulating pattern and may be interposed between the buried insulating pattern and the buried layer.

In general, according to some aspects, an image sensor may include a substrate having first and second surfaces facing each other and including a plurality of pixel regions, microlenses on the second surface of the substrate, a transfer gate disposed on the first surface of the substrate, a deep isolation pattern extending from the first surface into the substrate and interposed between the plurality of pixel regions, an anti-reflective layer on the deep isolation pattern, and a shallow device isolation pattern extending from the first surface into the substrate, the shallow device isolation pattern may be spaced apart from the deep isolation pattern, the deep isolation pattern may include a buried insulating pattern in contact with the first surface, an intervening insulating pattern on the buried insulating pattern, a buried layer on the intervening insulating pattern, a conductive liner on the buried layer, an insulating liner on the conductive liner, and a doped region on the insulating liner, and the intervening insulating pattern may surround side and upper surfaces of the buried insulating pattern and may be interposed between the buried insulating pattern and the buried layer.

### BRIEF DESCRIPTION OF THE DRAWINGS

Example implementations will be more clearly understood from the following brief description taken in conjunction with the accompanying drawings. The accompanying drawings represent non-limiting, example implementations as described herein.

FIG. 1 is a block diagram schematically illustrating an example of an image sensor.

FIG. 2 is a circuit diagram of an example of an active pixel sensor array of an image sensor.

FIG. 3 is a plan view of an example of an image sensor.

FIG. 4A is an example cross-sectional view taken along line A-A′ of FIG. 3.

FIG. 4B is an example cross-sectional view taken along line B-B′ of FIG. 3.

FIG. 4C is an example cross-sectional view taken along line C-C′ of FIG. 3.

FIG. 5A is a diagram illustrating an example of an image sensor and is an example cross-sectional view corresponding to line A-A′ of FIG. 3.

FIG. 5B is a diagram illustrating an example of an image sensor and is an example cross-sectional view taken along line B-B′ of FIG. 3.

FIGS. 6A to 19C are diagrams illustrating an example of a method of fabricating an image sensor, and are example cross-sectional views corresponding to lines A-A′, B-B′, and C-C′ of FIG. 3.

FIGS. 20A to 21C are diagrams illustrating an example of a method of fabricating an image sensor, and are example cross-sectional views corresponding to lines A-A′, B-B′, and C-C′ of FIG. 3.

### DETAILED DESCRIPTION

Hereinafter, the concept will be described in detail by explaining implementations of the concept with reference to the accompanying drawings.

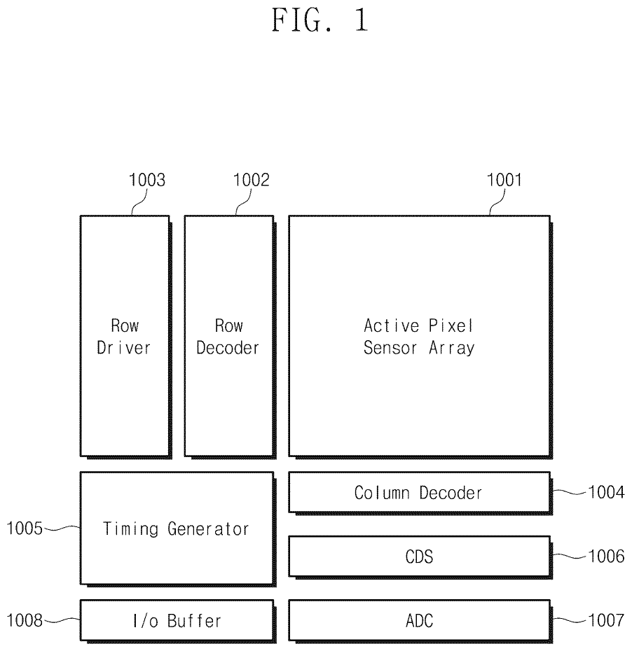

FIG. 1 is a block diagram schematically illustrating an example of an image sensor.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels two-dimensionally arranged and may convert optical signals into electrical signals. The active pixel sensor array 1001 may be driven by a plurality of driving signals (e.g., a pixel selection signal, a reset signal, and a charge transfer signal) provided from the row driver 1003. In addition, the converted electrical signals may be provided to the correlated double sampler 1006.

The row driver 1003 may provide a plurality of driving signals for driving a plurality of the unit pixels to the active pixel sensor array 1001 based on signals decoded in the row decoder 1002. When the unit pixels are arranged in a matrix form, the driving signals may be provided in the unit of row of the matrix.

The timing generator 1005 may provide timing signals and control signals to the row decoder 1002 and the column decoder 1004.

The correlated double sampler 1006 may receive electrical signals generated from the active pixel sensor array 1001 and may hold and sample the received electrical signals. The correlated double sampler 1006 may doubly sample a specific noise level and a signal level of the electrical signal to output a difference level corresponding to a difference between the noise level and the signal level.

The analog-to-digital converter 1007 may convert an analog signal, which corresponds to the difference level outputted from the correlated double sampler 1006, into a digital signal and may output the digital signal.

The I/O buffer 1008 may latch the digital signals and may sequentially output the latched digital signals to an image signal processing unit based on signals decoded in the column decoder 1004.

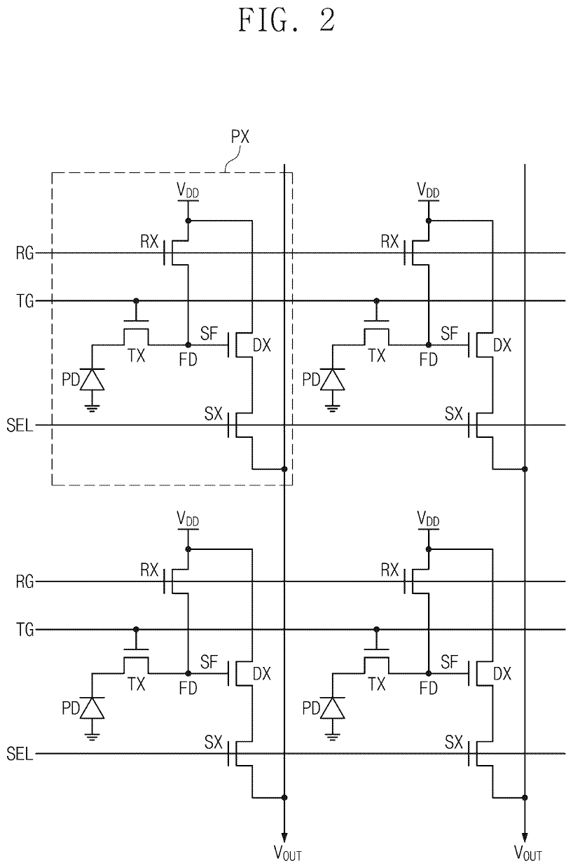

FIG. 2 is a circuit diagram of an example of an active pixel sensor array of an image sensor.

Referring to FIGS. 1 and 2, the active pixel sensor array 1001 may include a plurality of unit pixel regions PX, and the plurality of unit pixel regions PX may be arranged in a matrix form. Each of the unit pixel regions PX may include a transfer transistor TX. Each of the unit pixel regions PX may further include logic transistors RX, SX and DX. The logic transistors may include a reset transistor RX, a selection transistor SX, and a source follower transistor DX. The transfer transistor TX may include a transfer gate TG. Each of the unit pixel regions PX may further include a photoelectric converter PD and a floating diffusion region FD. The logic transistor RX, SX, and DX may be shared among the plurality of pixel region PX.

The photoelectric converter PD may generate photocharges (or charges) in proportion to the amount of light incident from the outside and may accumulate the generated photocharges. The photoelectric converter PD may include a photodiode, a photo transistor, a photo gate, a pinned photodiode, or a combination thereof. The transfer transistor TX may transfer charges generated in the photoelectric converter PD to the floating diffusion region FD. The floating diffusion region FD may receive the charges generated in the photoelectric converter PD and may cumulatively store the received charges. The source follower transistor DX may be controlled according to the amount of the photocharges accumulated in the floating diffusion region FD.

The reset transistor RX may periodically reset the charges accumulated in the floating diffusion region FD. A drain electrode of the reset transistor RX may be connected to the floating diffusion region FD, and a source electrode of the reset transistor RX may be connected to a power voltage VDD. When the reset transistor RX is turned on, the power voltage VDD connected to the source electrode of the reset transistor RX may be applied to the floating diffusion region FD. Thus, when the reset transistor RX is turned on, the charges accumulated in the floating diffusion region FD may be discharged to reset the floating diffusion region FD.

The source follower transistor DX including a source follower gate electrode SF may function as a source follower buffer amplifier. The source follower transistor DX may amplify a potential change in the floating diffusion region FD and may output the amplified potential change to an output line VOUT.

The selection transistor SX may select the unit pixel regions PX to be sensed in the unit of row. When the selection transistor SX is turned on, the power voltage VDD may be applied to a drain electrode of the source follower transistor DX.

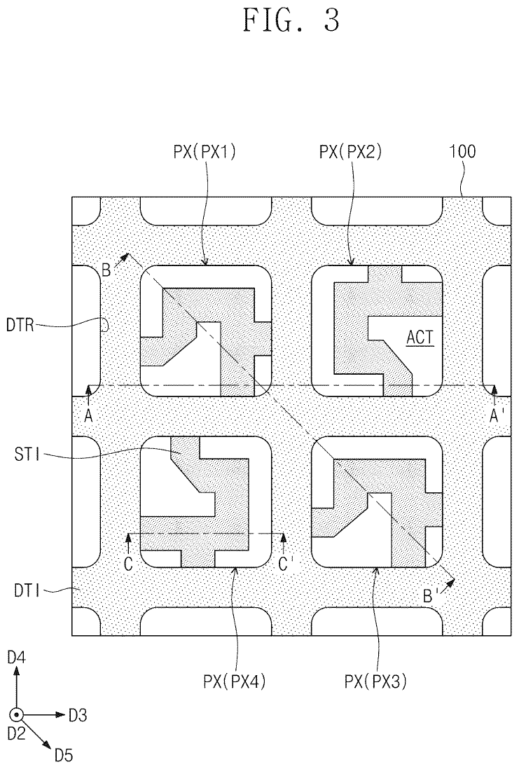

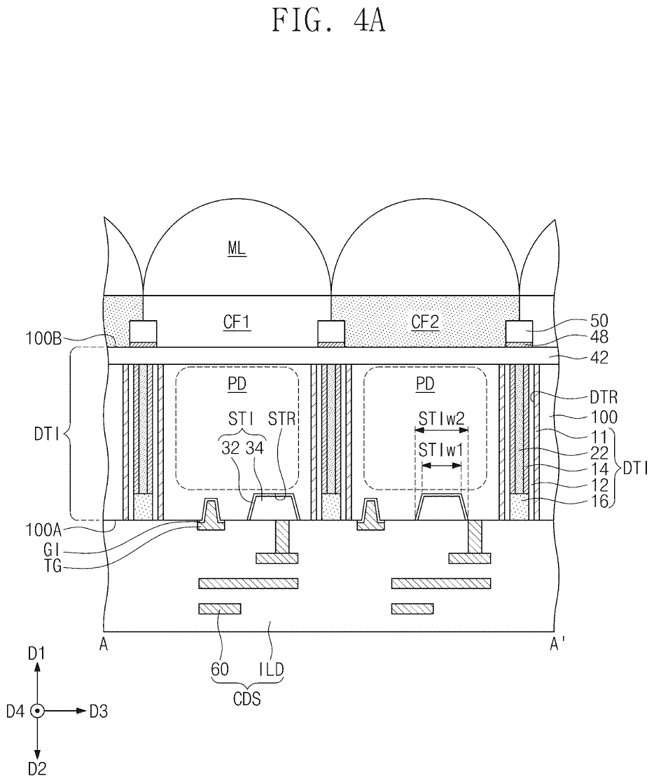

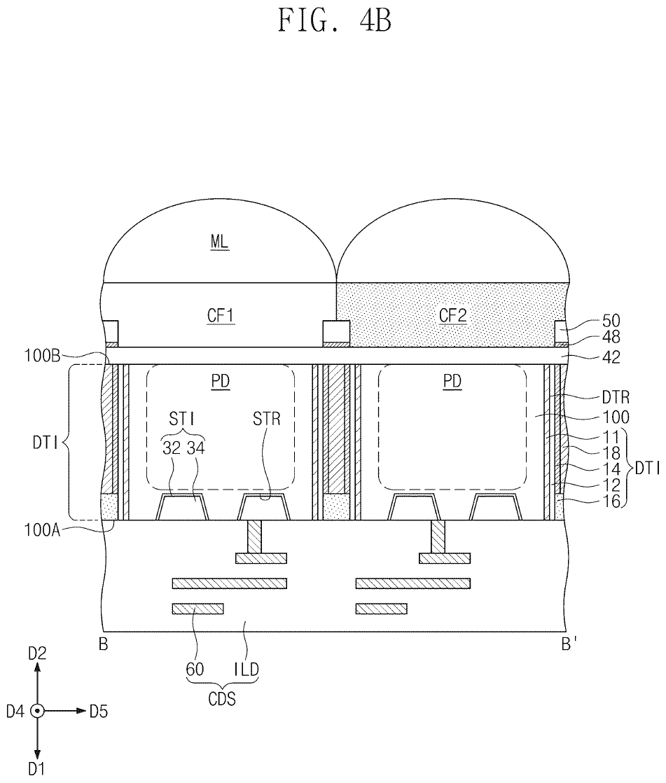

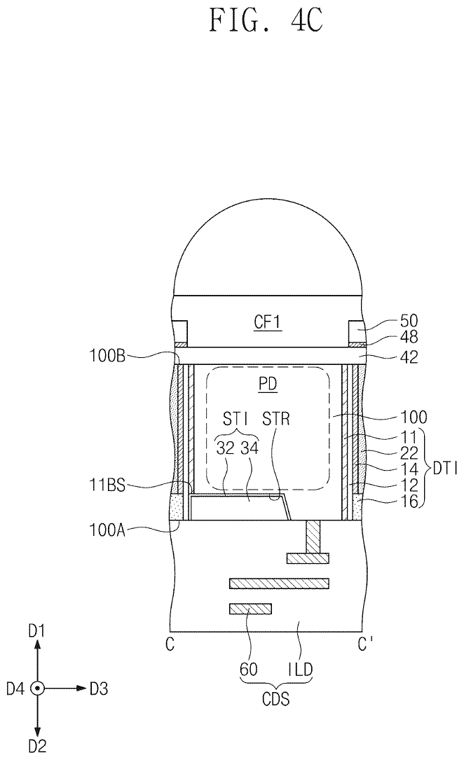

FIG. 3 is a plan view of an example of an image sensor. FIG. 4A is an example cross-sectional view taken along line A-A′ of FIG. 3. FIG. 4B is an example cross-sectional view taken along line B-B′ of FIG. 3. FIG. 4C is an example cross-sectional view taken along line C-C′ of FIG. 3.

Referring to FIG. 3, a substrate 100 may be provided. The substrate 100 may be, for example, a silicon single crystal wafer, a silicon epitaxial layer, or a silicon on insulator (SOI) substrate. For example, the substrate 100 may be doped with impurities having a first conductivity type (e.g., P type). The substrate 100 may include a first surface 100A and a second surface 100B that face each other. The first surface 100A may face a second direction D2, and the second surface 100B may face a first direction D1. The first direction D1 and the second direction D2 may face each other.

The substrate 100 may include a plurality of pixel regions PX. For example, when viewed in a plan view, the substrate 100 may include first, second, third, and fourth pixel regions PX1, PX2, PX3, and PX4 sequentially arranged in a clockwise direction. The first and second pixel regions PX1 and PX2 may be arranged side by side in a third direction D3, and the third and fourth pixel regions PX3 and PX4 may also be arranged side by side in the third direction D3. The third direction D3 may be parallel to the second surface 100B of the substrate 100. The second and third pixel regions PX2 and PX3 may be arranged side by side in a fourth direction D4, and the first and fourth pixel regions PX1 and PX4 may also be arranged side by side in the fourth direction D4. The fourth direction D4 may be parallel to the second surface 100B of the substrate 100 and intersect the third direction D3.

A deep isolation pattern DTI may be disposed in the substrate 100. The deep isolation pattern DTI may separate the pixel regions PX. The deep isolation pattern DTI may penetrate the substrate 100 in the second direction D2 between the pixel regions PX.

The deep isolation pattern DTI may be disposed in an isolation trench DTR extending from the first surface 100A toward the second surface 100B. When viewed in a plan view, the deep isolation pattern DTI may have a mesh shape where lines extending in the third and fourth directions D3 and D4 intersect.

The deep isolation pattern DTI may extend from the first surface 100A into the substrate 100 and may be interposed between the plurality of pixel regions PX. The deep isolation pattern DTI may penetrate the substrate 100. A width of the deep isolation pattern DTI may be constant regardless of a distance from the first surface 100A of the substrate 100.

A shallow device isolation pattern STI may be disposed in the substrate 100. The shallow device isolation pattern STI may extend from the first surface 100A into the substrate 100 and may be disposed in a corresponding pixel region among the plurality of pixel regions PX. The shallow device isolation pattern STI may define active regions ACT adjacent to the first surface 100A of the substrate 100 in the pixel region PX. The active regions ACT may be provided for the transistors TX, RX, DX, and SX of FIG. 2.

Referring to FIGS. 4A and 4C, a cross section of the image sensor of FIG. 3 cut in the third direction D3 is described in detail.

The deep isolation pattern DTI may include a buried insulating pattern 16, a buried layer 22 on the buried insulation pattern 16, a conductive liner 14 on the buried layer 22, an insulating liner 12 in contact with the buried insulating pattern 16 and the conductive liner 14, and a doped region 11 on the insulating liner 12.

The buried insulating pattern 16 may be provided on the first surface 100A of the substrate 100. A lower surface of the buried insulating pattern 16 may be in contact with the first surface 100A of the substrate 100. The buried insulating pattern 16 may include an insulating material. The buried insulating pattern 16 may include, for example, oxide. The upper surface of the buried insulating pattern 16 may be in contact with the buried layer 22 and the conductive liner 14.

The buried insulating pattern 16 may include oxide. A distance from the first surface 100A of the substrate 100 to an upper surface of the buried insulating pattern 16 may be 500 to 4000 Å.

The buried layer 22 may be provided on the buried insulating pattern 16. The buried layer 22 may include polysilicon or oxide. The buried layer 22 may include, for example, boron-doped silicon or undoped silicon. The buried layer 22 may include, for example, SiO₂.

The conductive liner 14 may be provided on the buried insulating pattern 16. The conductive liner 14 may surround a side surface of the buried layer 22. An upper surface of the conductive liner 14 and an upper surface of the buried layer 22 may be coplanar with the second surface 100B. An inner sidewalls of adjacent conductive liner 14 may be spaced apart by the buried layer 22. The inner sidewall of the conductive liner 14 may be in contact with the buried layer 22. An outer sidewall of the conductive liner 14 may be in contact with the insulating liner 12. The conductive liner 14 may include a conductive material. The conductive liner 14 may include silicon. The conductive liner 14 may include boron-doped silicon, for example.

The insulating liner 12 may be provided on the conductive liner 14. The insulating liner 12 may surround the outer sidewall of the conductive liner 14 and the sidewall of the buried insulating pattern 16. An upper surface of the insulating liner 12, an upper surface of the conductive liner 14, and an upper surface of the buried layer 22 may be coplanar with the second surface 100B. The inner sidewalls of adjacent insulating liners 12 may be spaced apart by the conductive liner 14 and the buried layer 22. The conductive liner 14 may be in contact with the buried insulating pattern 16 and the buried layer 22.

The insulating liner 12 may include oxide or nitride. The insulating liner 12 may include SiO₂ or Si₃N₄, for example. The buried layer 22 and insulating liner 12 may include different materials.

The doped region 11 may be provided on the insulating liner 12. The doped region 11 may surround a sidewall of the insulating liner 12. The doped region 11 may be p-type doped silicon. The doped region 11 may include boron, for example. The doped region 11 may include, for example, boron-doped silicon. The doped region 11 may be interposed between the substrate 100 and the insulating liner 12. A sidewall of the doped region 11 may be in contact with the substrate 100.

A shallow device isolation trench STR recessed from the first surface 100A of the substrate 100 into the substrate 100 may be provided, and the shallow device isolation pattern STI may fill the shallow device isolation trench STR. The shallow device isolation pattern STI may be disposed adjacent to the first surface 100A of the substrate.

The shallow device isolation pattern STI may include a first isolation portion 32 and a second isolation portion 34. The first isolation portion 32 may conformally cover an inner wall of the shallow device isolation trench STR. The second isolation portion 34 may fill an interior of the shallow device isolation trench STR. The first and second isolation portions 32 and 34 may independently include at least one of silicon oxide (SiO), silicon nitride (SiN), silicon carbonitride (SiCN), or silicon oxycarbonitride (SiOCN), or a combination thereof.

A width of the shallow device isolation pattern STI may decrease as a distance from the first surface 100A of the substrate 100 increases. An upper surface of the shallow device isolation pattern STI disposed inside the substrate 100 may have a first width STIw1. A lower surface of the shallow device isolation pattern STI in contact with the first surface 100A of the substrate 100 may have a second width STIw2. The second width STIw2 may be larger than the first width STIw1.

In some implementations, the shallow device isolation pattern STI may be spaced apart from the deep isolation pattern DTI. In this case, the active region ACT may be interposed between the shallow device isolation pattern STI and the deep isolation pattern DTI.

In some implementations, one sidewall of the insulating liner 12 of the deep isolation pattern DTI may be in contact with the shallow device isolation pattern STI, and the other sidewall of the deep isolation pattern DTI may be spaced apart from the shallow device isolation pattern STI. The other sidewall of the deep isolation pattern DTI may be in contact with the substrate 100. A lower surface 11BS of the doped region 11 of the deep isolation pattern DTI may be in contact with the shallow device isolation pattern STI. A lower surface 11BS of the doped region 11 may be in contact with the first isolation portion 32 of the shallow device isolation pattern STI. Referring to FIG. 4B, a cross section of the image sensor of FIG. 3 cut in a fifth direction D5 is described in more detail. The deep isolation pattern DTI surrounded by the first, second, third and fourth pixel regions PX1, PX2, PX3 and PX4, that is, the deep isolation pattern DTI disposed in a center of the first, second, third and fourth pixel regions PX1, PX2, PX3 and PX4, may further include a buried conductive layer 18.

The buried conductive layer 18 may be provided on the buried insulating pattern 16. A sidewall of the buried conductive layer 18 may be surrounded by the conductive liner 14. An upper surface of the buried conductive layer 18 and an upper surface of the conductive liner 14 may be coplanar with the second surface 100B. An inner sidewall of adjacent conductive liner 14 may be spaced apart by a buried conductive layer 18. The upper surface of the buried insulating pattern 16 may be in contact with the buried conductive layer 18 and the conductive liner 14. The buried conductive layer 18 may include a conductive material.

An anti-reflective layer 42 may be disposed on the deep isolation pattern DTI. The anti-reflective layer 42 may be provided on the second surface 100B of the substrate 100 and may cover the second surface 100B. A lower surface of the anti-reflective layer 42 may be in contact with the second surface 100B of the substrate 100 and the doped region 11.

The anti-reflective layer 42 may include oxide. The anti-reflective layer 42 may include, for example, Al₂O₃, HfO, SiO₂, or PTEOS.

A transfer gate TG may be provided on the first surface 100A of the substrate 100 in each pixel region PX. For example, a portion of the transfer gate TG may be buried inside the substrate 100. The transfer gate TG may be of vertical type. As another example, the transfer gate TG may be of a planar type that is flat on the first surface 100A of the substrate 100.

A gate insulating pattern GI may be interposed between the transfer gate TG and the substrate 100. A floating diffusion region may be provided in the substrate 100 adjacent to one side surface of the transfer gate TG. As an example, impurities having a second conductivity type may be doped into the floating diffusion region.

In some implementations, light may be incident into the substrate 100 through the second surface 100B of the substrate 100. Electron-hole pairs may be generated at a PN junction by incident light. The electrons generated in this way may move to a photoelectric converter PD. The electrons may move to the floating diffusion region as a voltage is applied to the transfer gate TG.

A conductive structure CDS may be provided on the first surface 100A of the substrate 100. The conductive structure CDS may include an interlayer insulating layer ILD and wirings 60.

The interlayer insulating layer ILD may be provided on the first surface 100A of the substrate 100 and may cover the first surface 100A. The interlayer dielectric layer ILD may be a composite layer including at least one of a silicon oxide layer, a silicon nitride layer, a silicon oxynitride layer, a porous low dielectric layer, or a combination thereof. The wirings 60 may be provided in the interlayer insulating layer ILD. The floating diffusion region may be connected to the wirings 60.

A photoelectric converter PD may be provided in each of the pixel regions PX. The photoelectric converter PD may be doped with impurities having a second conductivity type (e.g., N-type) opposite to the first conductivity type. The impurities doped in the photoelectric converter PD may form a PN junction with the impurities having the first conductivity type in the substrate 100, and a photodiode may be provided therethrough.

Light-shielding patterns 48 may be disposed on the anti-reflective layer 42. Low refractive patterns 50 may be respectively disposed on the light-shielding patterns 48. The light-shielding pattern 48 and the low refractive pattern 50 overlap the deep isolation pattern DTI and may have a two-dimensional grid shape. The light-shielding pattern 48 may include titanium, for example. The low refractive patterns 50 have the same thickness and may include the same organic material. The low refractive pattern 50 may have a smaller refractive index than that of color filters CF1 and CF2, which will be described later. The light-shielding pattern 48 and the low refractive pattern 50 may prevent crosstalk between adjacent pixel regions PX.

Color filters CF1 and CF2 may be disposed between the low refractive patterns 50. The color filters CF1 and CF2 may each have one of blue, green, and red. As another example, the color filters CAF1 and CF2 may include other colors such as cyan, magenta, or yellow. In the image sensor according to this example, the color filters CF1 and CF2 may be arranged in a Bayer pattern. In another example, the color filters CF1 and CF2 may be arranged in a 2×2 array of tetra patterns, 3×3 arrays of nona patterns, or 4×4 arrays of hexadeca patterns.

Microlenses ML may be disposed on the color filters CF1 and CF2. Edges of the microlenses ML may be in contact with each other and connected to each other.

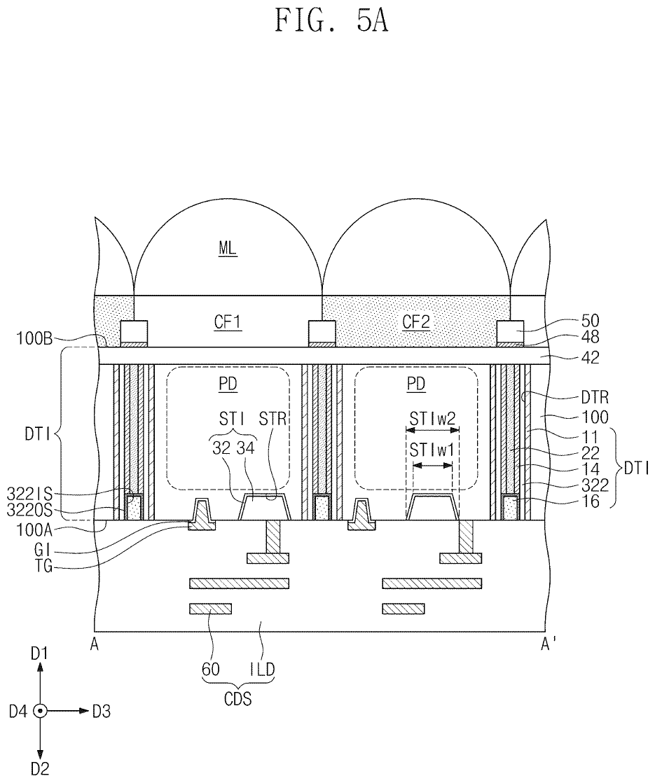

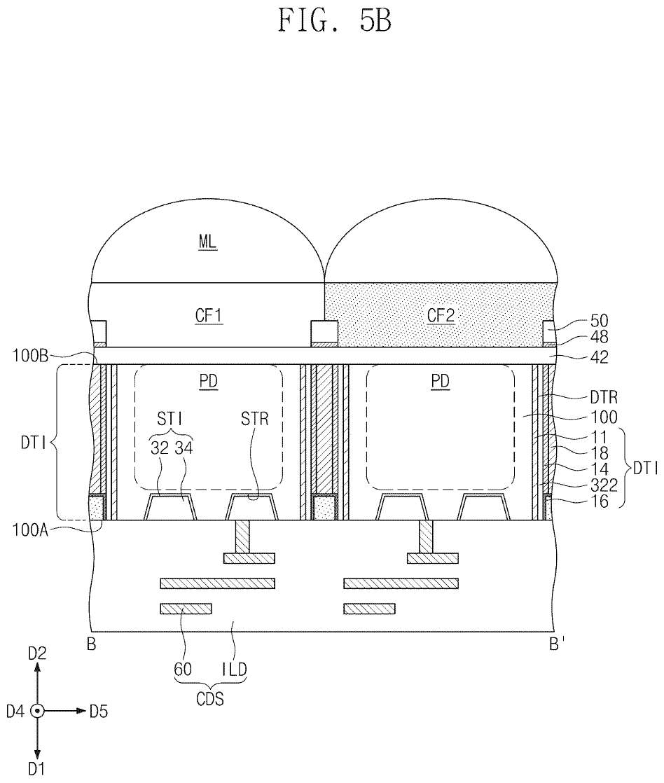

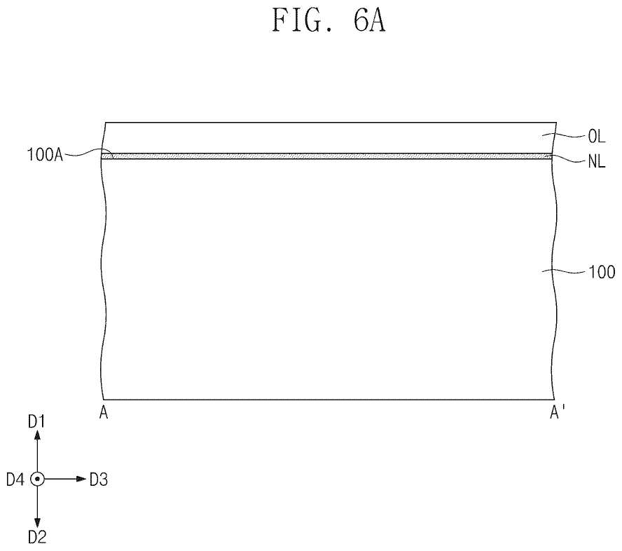

FIG. 5A is a diagram illustrating an example of an image sensor and is an example cross-sectional view corresponding to line A-A′ of FIG. 3. FIG. 5B is a diagram illustrating an example of an image sensor and is an example cross-sectional view taken along line B-B′ of FIG. 3. For simplicity of explanation, description of content that overlaps with the above-mentioned content is omitted.

Referring to FIGS. 3 and 5A, a cross-section of the image sensor of FIG. 3 taken in the third direction D3 according to some implementations will be described in detail.

A deep isolation pattern DTI may be disposed in the substrate 100. The deep isolation pattern DTI may include a buried insulating pattern 16, an intervening insulating pattern 322 on the buried insulating pattern 16, a buried layer 22 on the intervening insulating pattern 322, a conductive liner 14 on the buried layer 22, an insulating liner 12 on a conductive liner 14, and a doped region 11 on insulating liner 12.

The intervening insulating pattern 322 may surround the buried insulating pattern 16. The intervening insulating pattern 322 may be disposed between the insulating liner 12 and the buried insulating pattern 16, between the buried layer 22 and the buried insulating pattern 16, and between the conductive liner 14 and the buried insulating pattern 16. The intervening insulating pattern 322 may include nitride (silicon nitride, Si₃N₄).

The intervening insulating pattern 322 may surround side and upper surfaces of the buried insulating pattern 16. An inner wall 322IS of the intervening insulating pattern 322 may be in contact with the buried insulating pattern 16. An outer wall 322OS of the intervening insulating pattern 322 may be in contact with the insulating liner 12. An upper surface of the intervening insulating pattern 322 may be in contact with the conductive liner 14 and the buried layer 22.

Referring to FIGS. 3 and 5B, a cross-section of the image sensor of FIG. 3 taken in a fifth direction D5 according to some implementations will be described in detail.

A deep isolation pattern DTI may further include a buried conductive layer 18. The buried conductive layer 18 may be provided on the intervening insulating pattern 322. The intervening insulating pattern 322 may be provided to surround the buried insulating pattern 16. The buried conductive layer 18 and the conductive liner 14 surrounding the buried conductive layer 18 may be provided on the intervening insulating pattern 322. The upper surface of the intervening insulating pattern 322 may be in contact with the conductive liner 14 and the buried conductive layer 18.

The intervening insulating pattern 322 may be disposed between the insulating liner 12 and the buried insulating pattern 16, between the buried conductive layer 18 and the buried insulating pattern 16, and between the conductive liner 14 and the buried insulating pattern 16.

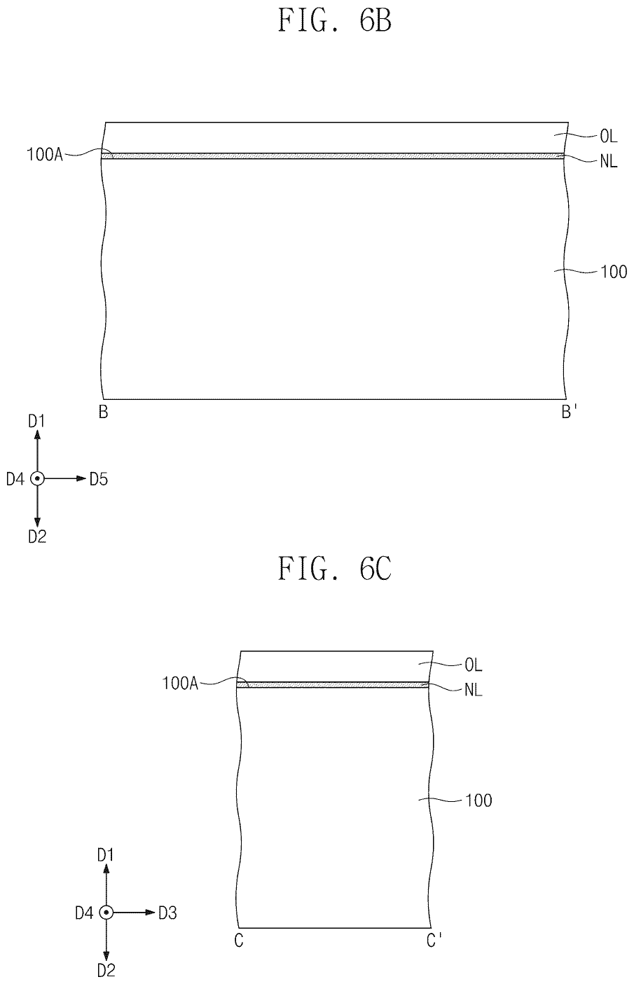

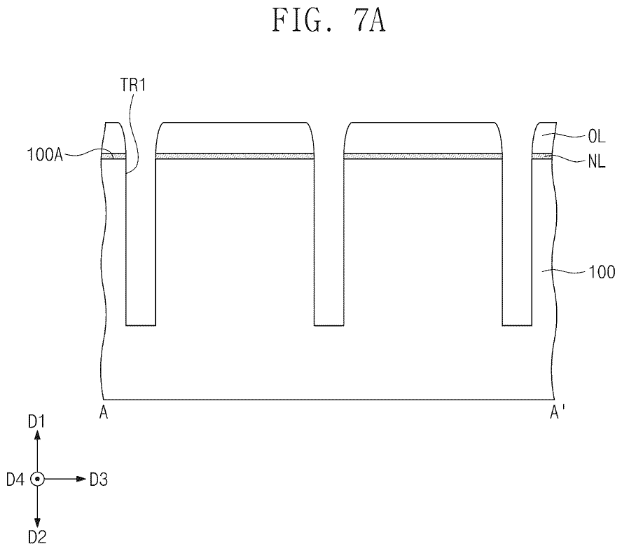

FIGS. 6A to 19C are diagrams illustrating an example of a method of fabricating an image sensor, and are example cross-sectional views corresponding to lines A-A′, B-B′, and C-C′ of FIG. 3.

Referring to FIGS. 6A, 6B, and 6C, a substrate 100 may be prepared. A first insulating layer NL may be formed on a first surface 100A of the substrate 100, and a second insulating layer OL may be formed on the first insulating layer NL. The first insulating layer NL may include an insulating material. The first insulating layer NL may include, for example, oxide or nitride. For example, the first insulating layer NL may include SiO₂, Si₃N₄, or a composite layer (double layer) thereof. The second insulating layer OL may include an insulating material. The second insulating layer OL may include, for example, oxide. A height of the first insulating layer NL in the first direction D1 may be smaller than a height of the second insulating layer OL in the first direction D1. For example, the first insulating layer OL and the second insulating layer OL may be formed to serve as a mask layer.

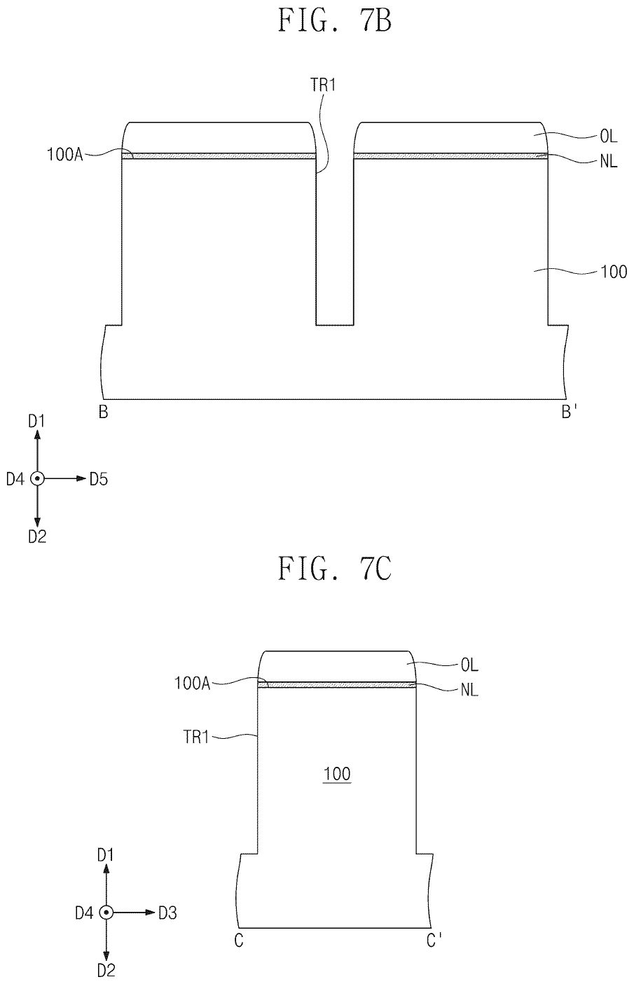

Referring to FIGS. 7A, 7B, and 7C, a first trench TR1 recessed from the first surface 100A of the substrate 100 into the substrate 100 may be formed. The first trench TR1 may be formed to penetrate a portion of the substrate 100. When viewed in a plan view, the first trench TR1 may have a mesh shape where lines extending in the third and fourth directions D3 and D4 intersect. An interior of the substrate 100 may be exposed by the first trench TR1. The first trench TR1 may define a location of the pixel region PX.

Forming the first trench TR1 may include etching the substrate 100 using the first insulating layer NL and the second insulating layer OL on the first surface 100A of the substrate 100 as an etch mask. A portion of the first insulating layer NL and the second insulating layer OL may remain as an etch mask.

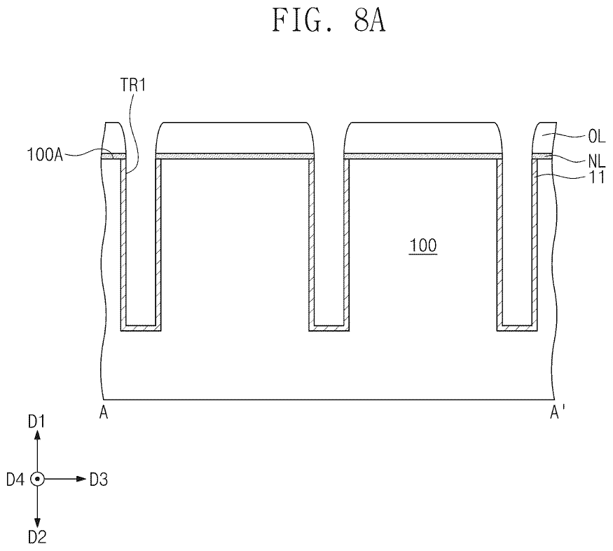

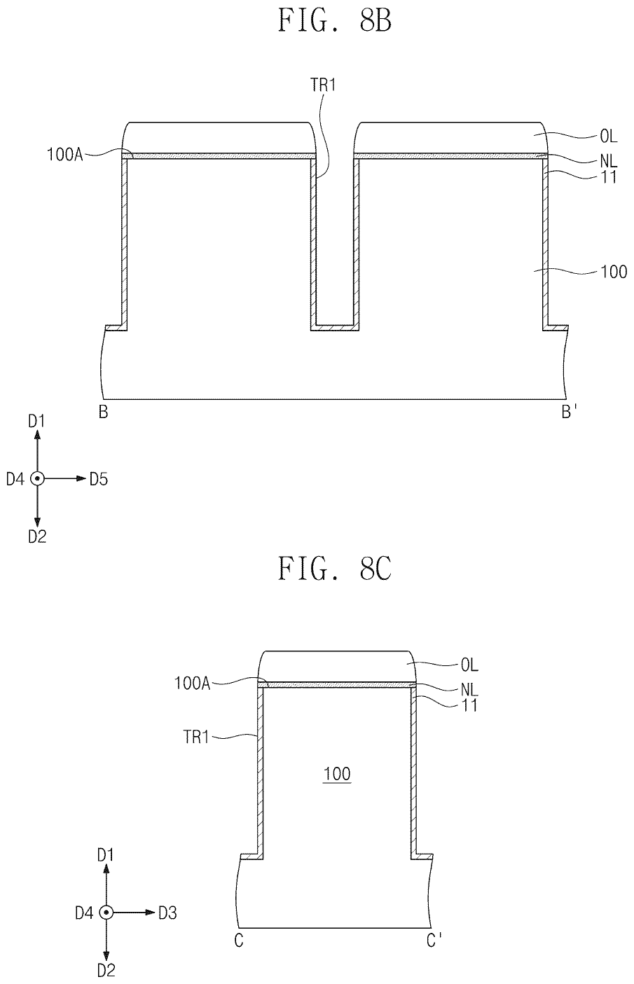

Referring to FIGS. 8A, 8B, and 8C, a doped region 11 may be formed along an inner wall of the first trench TR1. The doped region 11 may be formed, for example, through boron doping along the inner wall of the first trench TR1.

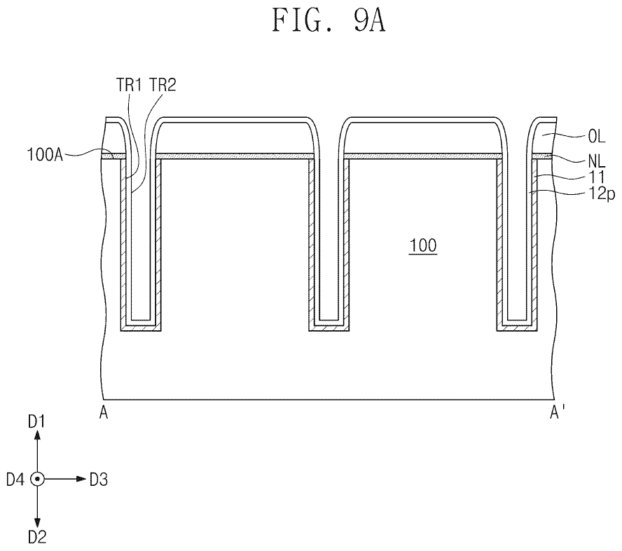

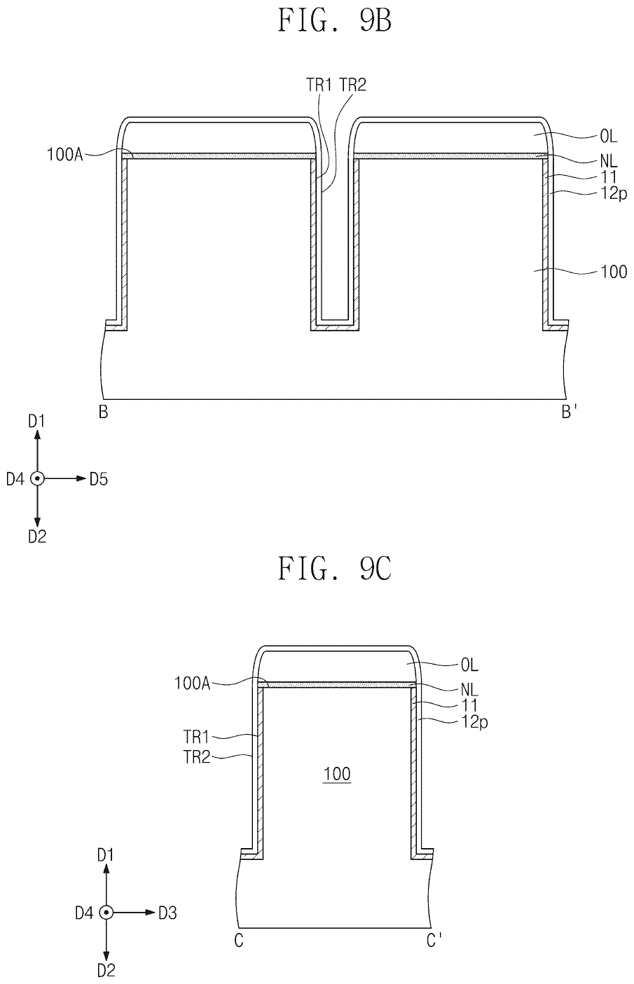

Referring to FIGS. 9A, 9B, and 9C, an insulating liner layer 12p may be formed to conformally cover the inner wall of the first trench TR1. The insulating liner layer 12p may be formed to cover sidewalls of the first insulating layer NL and sidewalls and upper surface of the second insulating layer OL. The insulating liner layer 12p may include silicon oxide (SiO). As an example, the insulating liner layer 12p may further include a material other than silicon oxide (e.g., silicon nitride (SiN), silicon carbonitride (SiCN), silicon oxycarbonitride (SiOCN), etc.). The insulating liner layer 12p may be a single layer or a composite layer including two or more layers. The insulating liner layer 12p may form a second trench TR2 while conformally covering the inner wall of the first trench TR1.

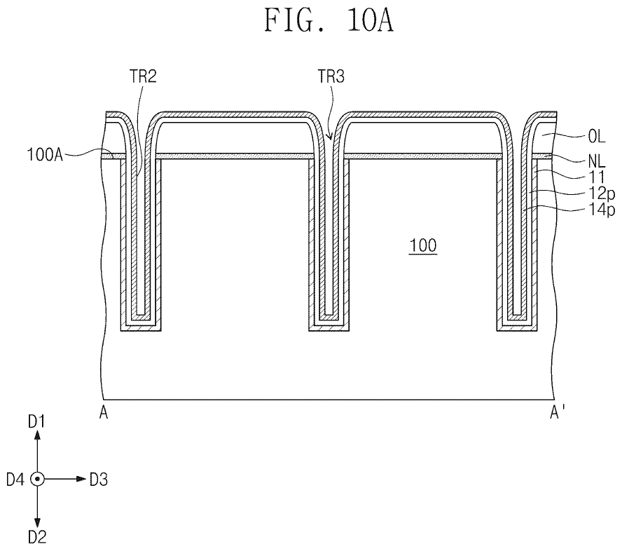

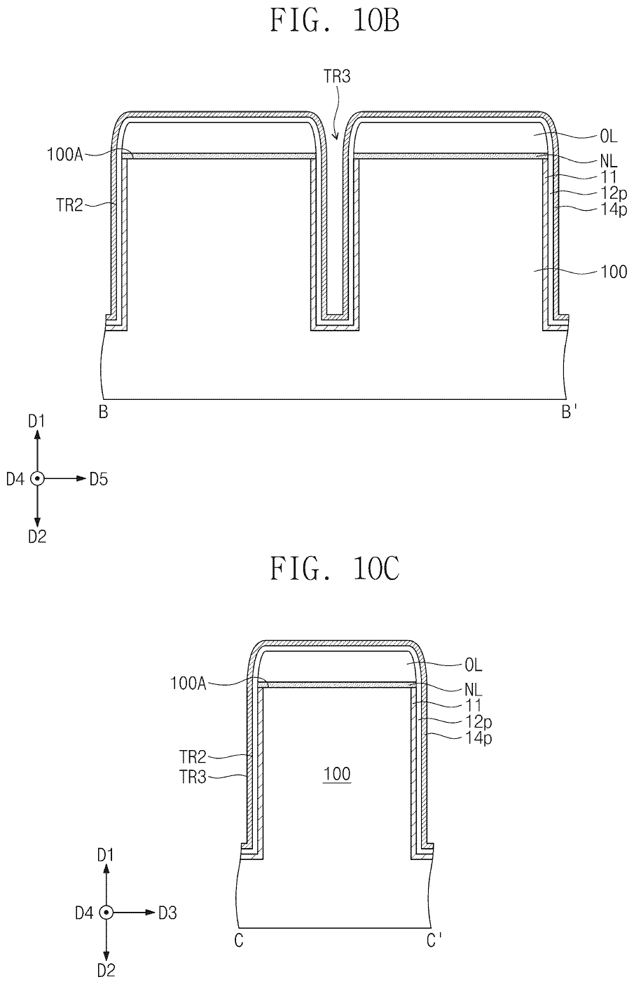

Referring to FIGS. 10A, 10B, and 10C, a preliminary conductive liner 14p may be formed on the insulating liner layer 12P. The preliminary conductive liner 14p may conformally cover an inner wall of the second trench TR2. The preliminary conductive liner 14p may include a conductive material. The preliminary conductive liner 14p may be formed to form a third trench TR3

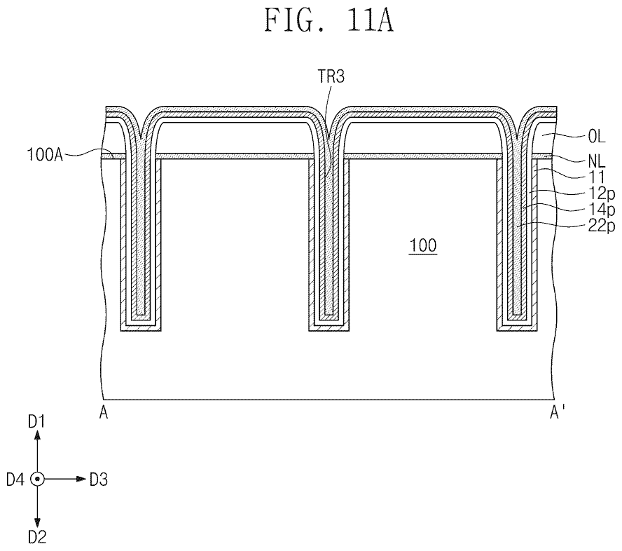

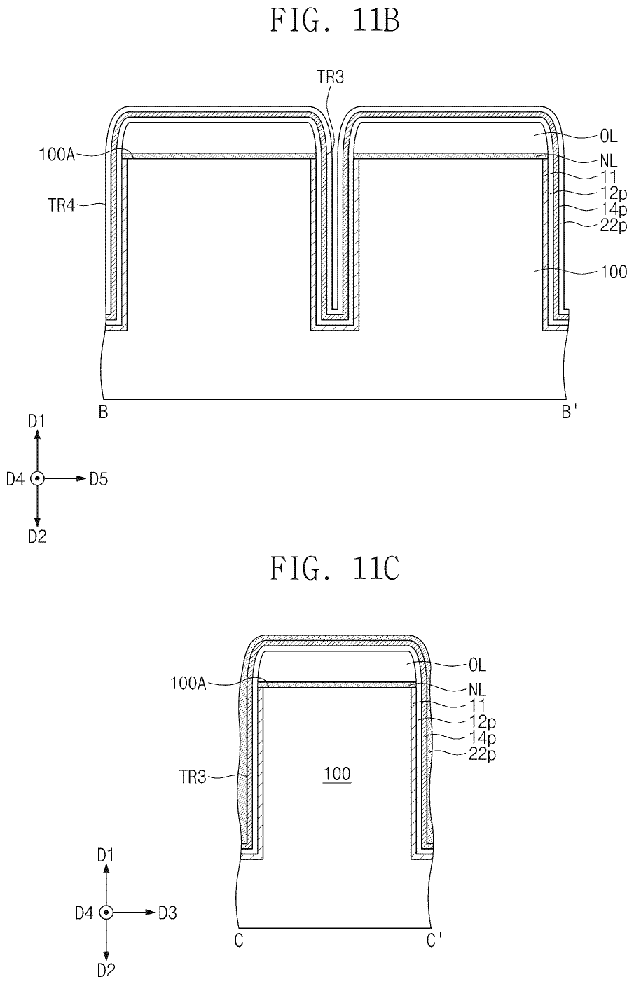

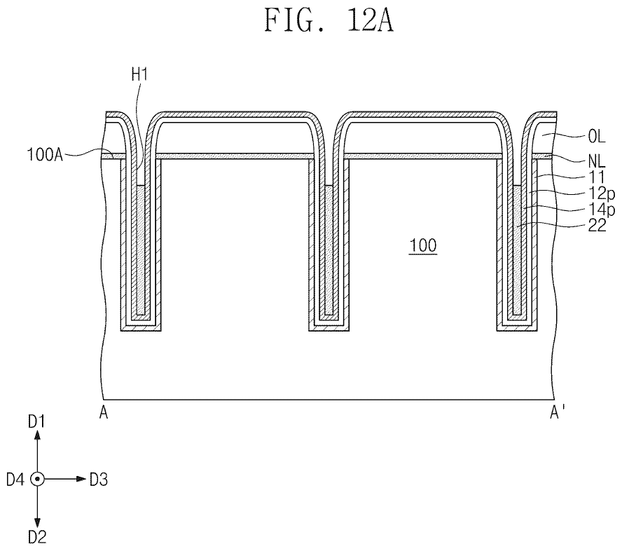

Referring to FIGS. 11A, 11B, and 11C, a first insulating pattern 22p may be formed on the preliminary conductive liner 14p. The first insulating pattern 22p may conformally cover an inner wall of the third trench TR3.

Referring again to FIGS. 11A and 11C, a fabricating method corresponding to the cross section of the image sensor of FIG. 3 cut in the third direction D3 will be described in detail. The first insulating pattern 22p may be formed between the first pixel PX1 and the second pixel PX2 to completely fill the third trench TR3. The first insulating pattern 22p may be formed to completely fill the third trench TR3 and conformally cover the preliminary conductive liner 14p.

Referring again to FIG. 11B, a fabricating method corresponding to the cross section of the image sensor of FIG. 3 cut in the fifth direction D5 will be described in detail. In a portion surrounded by the first to fourth pixels PX1, PX2, PX3, and PX4, the first insulating pattern 22p may be formed along the inner wall of the third trench TR3. The first insulating pattern 22p may be formed to conformally cover the third trench TR3. The first insulating pattern 22p may be formed to form a fourth trench TR4.

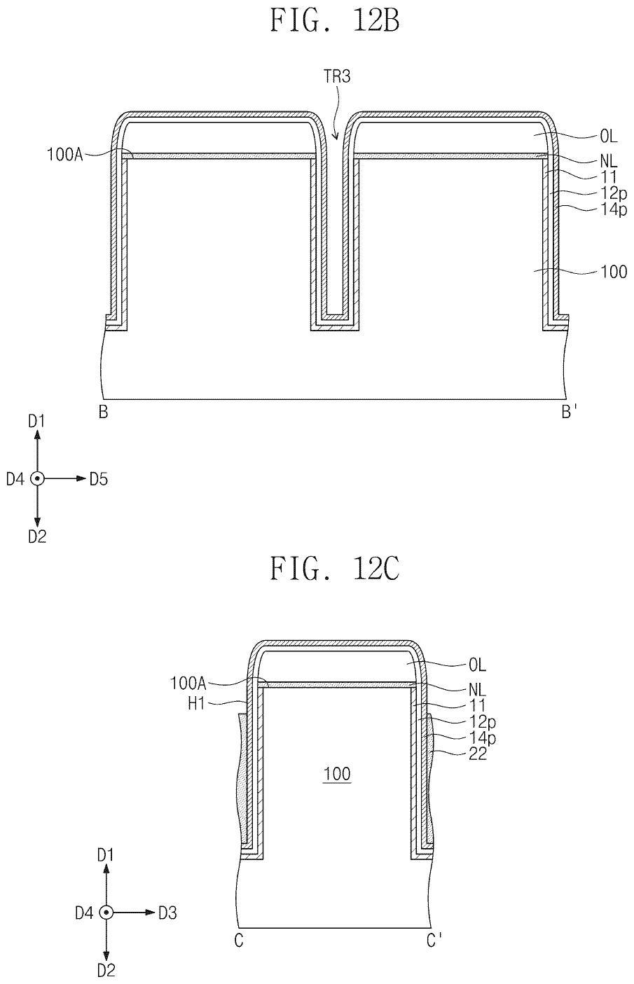

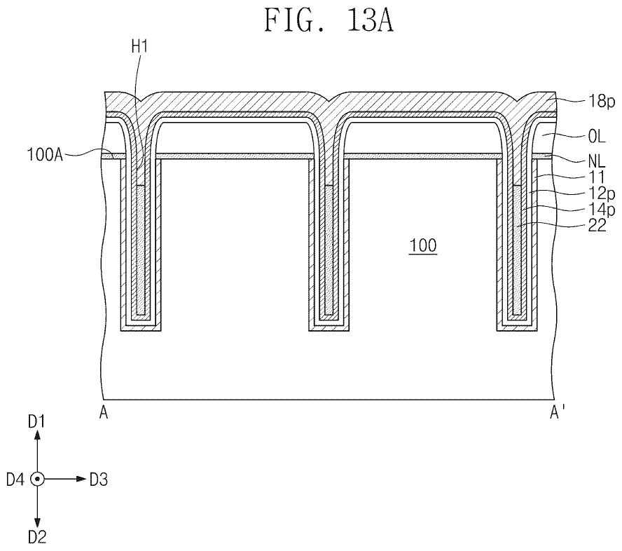

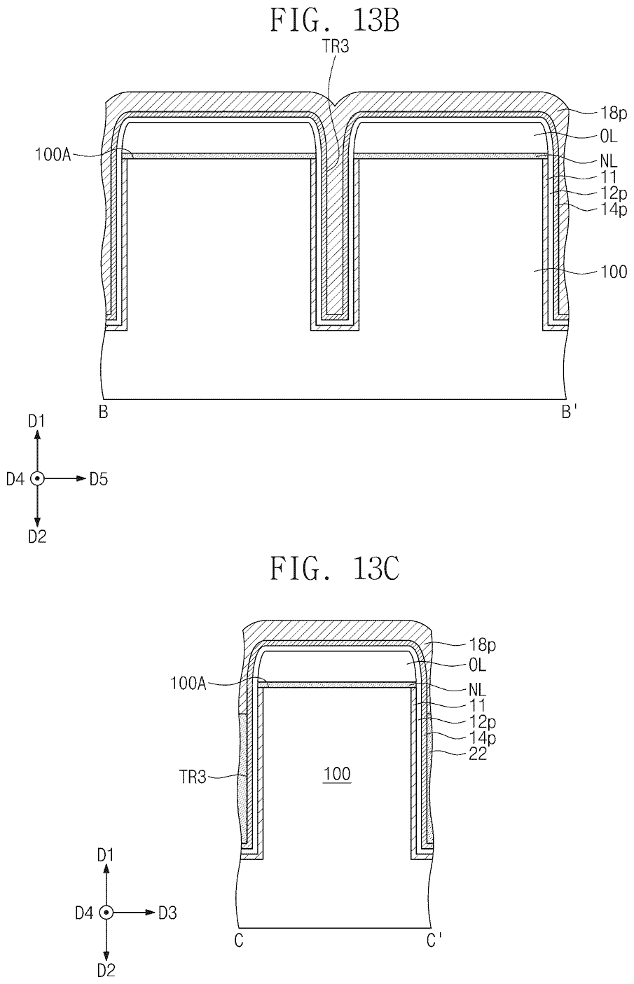

Referring to FIGS. 12A, 12B, and 12C, an upper portion of the first insulating pattern 22p may be removed.

Referring to FIGS. 12A and 12C, removing the upper portion of the first insulating pattern 22p between the first pixel PX1 and the second pixel PX2, may include for example, partially removing the first insulating pattern 22p in an intervening region IR until the first insulating pattern 22p remains at a level below the first surface 100A of the substrate 100. The upper portion of the first insulating pattern 22p may be removed to form a buried layer 22. An upper portion of the first insulating pattern 22p may be removed and a first hole H1 may be formed by an exposed sidewall of the preliminary conductive liner 14P, on an upper surface of the buried layer 22.

Referring to FIG. 12B, in a portion surrounded by the first to fourth pixels PX1, PX2, PX3, and PX4, removing the upper portion of the first insulating pattern 22p may include, for example, removing all of the first insulating patterns 22p so that no first insulating patterns 22p are left behind. In this case, the third trench TR3 may be exposed again. The buried layer 22 may be formed by removing the upper portion of the first insulating pattern 22p.

Referring to FIGS. 13A, 13B, and 13C, a preliminary buried conductive layer 18p may be formed on the buried layer 22 and the preliminary conductive liner 14p. The preliminary buried conductive layer 18p may be formed to fill the first hole H1 and the exposed portion of the third trench TR3. The preliminary buried conductive layer 18p may include a conductive material.

Referring to FIGS. 13A and 13C, forming the preliminary buried conductive layer 18p between the first pixel PX1 and the second pixel PX2 may include filling the first hole H1 with the preliminary buried conductive layer 18p and covering an upper surface of the preliminary conductive liner 14p.

Referring again to FIG. 13B, in a portion surrounded by the first to fourth pixels PX1, PX2, PX3, and PX4, the preliminary buried conductive layer 18p may be formed to fill the third trench TR3. The preliminary buried conductive layer 18p may be formed to cover the upper surface of the preliminary conductive liner 14p.

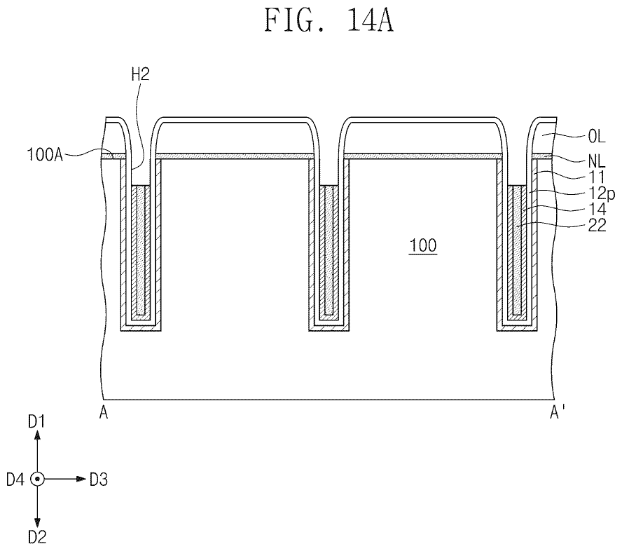

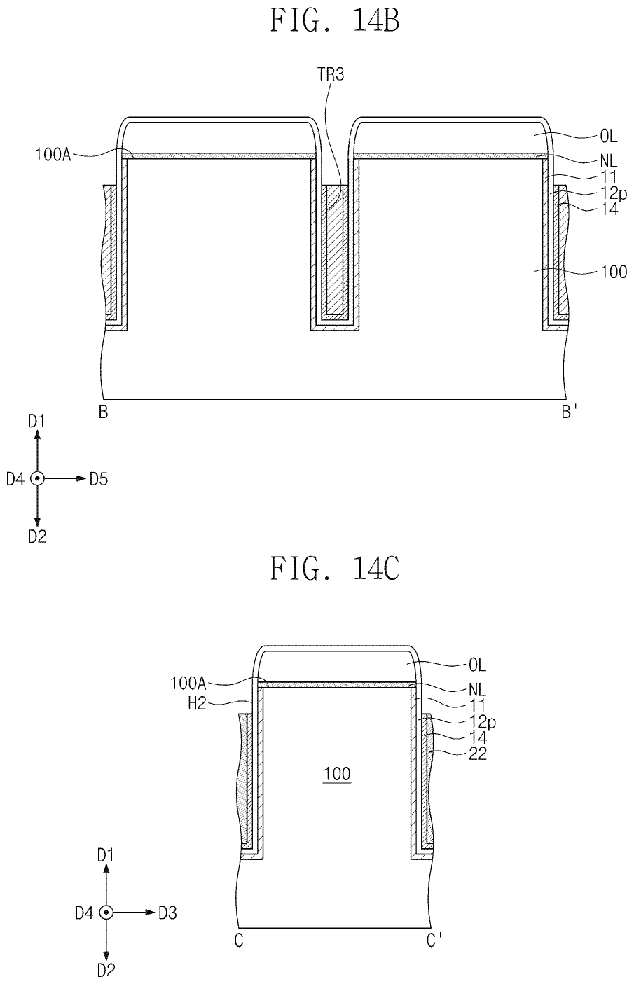

Referring to FIGS. 14A, 14B, and 14C, the preliminary buried conductive layer 18p and the preliminary conductive liner 14p may be partially removed.

Referring to FIGS. 14A and 14C, removing the preliminary buried conductive layer 18p between the first pixel PX1 and the second pixel PX2 may include removing all of the preliminary buried conductive layer 18p so that no preliminary buried conductive layer 18p is left behind. Removing the preliminary buried conductive layer 18p may include removing an upper portion of the preliminary conductive liner 14p. As the upper portion of the preliminary conductive liner 14p is removed, a conductive liner 14 may be formed. As the upper portion of the preliminary conductive liner 14p and the preliminary buried conductive layer 18 are removed, a second hole H2 may be formed. The second hole H2 may be defined by an upper surface of the conductive liner 14, an upper surface of the buried layer 22, and the exposed insulating liner layer 12P.

Referring to FIG. 14b, in a portion surrounded by the first to fourth pixels PX1, PX2, PX3, and PX4, partially removing the preliminary buried conductive layer 18p and the preliminary conductive liner 14p may include, for example, removing an upper portion of the buried conductive layer 18p and removing an upper portion of the preliminary conductive liner 14p. A portion of the preliminary buried conductive layer 18p may remain without being removed. The upper portion of the preliminary buried conductive layer 18p may be removed to form a buried conductive layer 18. The upper portion of the preliminary buried conductive layer 18p may be removed to form a second hole H2. The second hole H2 may be defined by the upper surface of the buried conductive layer 18 and the exposed portion of the insulating liner layer 12P.

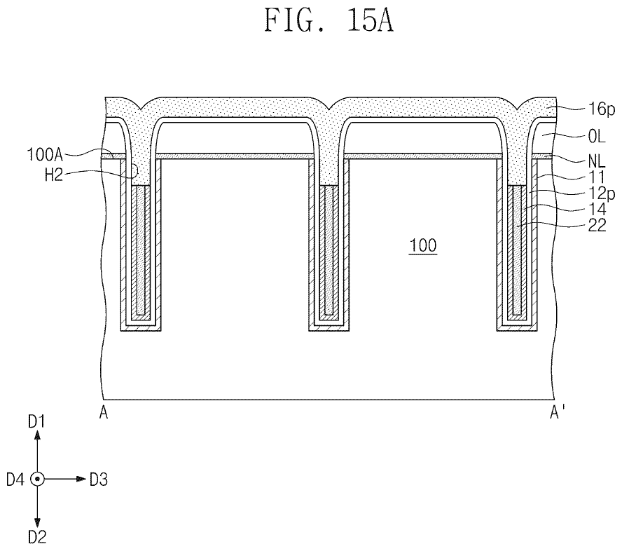

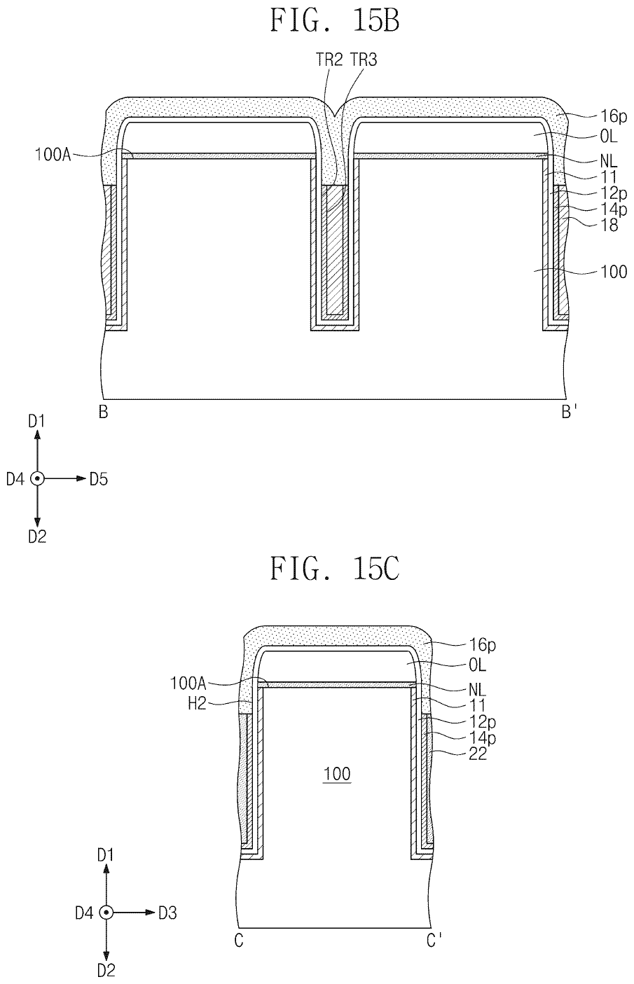

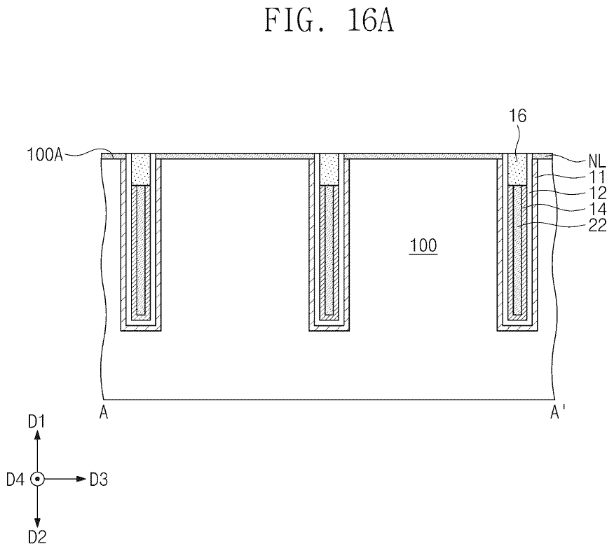

Referring to FIGS. 15A, 15B, and 15C, a preliminary buried insulating pattern 16p may be formed on the buried layer 22, the conductive liner 14, and the insulating liner layer 12P. The preliminary buried insulating pattern 16p may be formed on the buried conductive layer 18. The preliminary buried insulating pattern 16p may be formed to fill the second hole H2. According to some implementations, an annealing process may be additionally performed after forming the preliminary buried insulating pattern 16p.

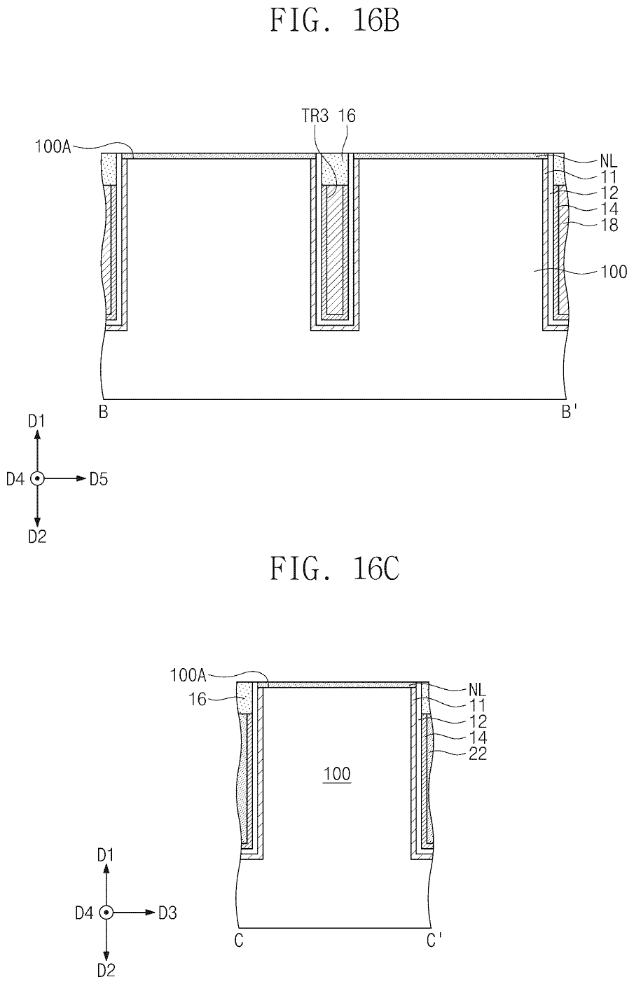

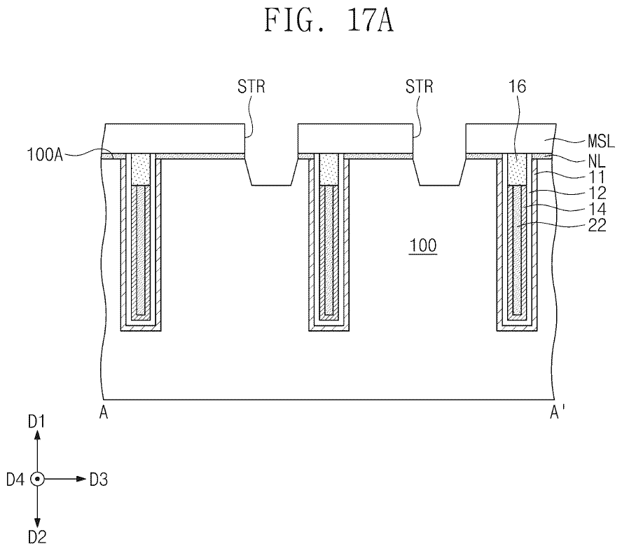

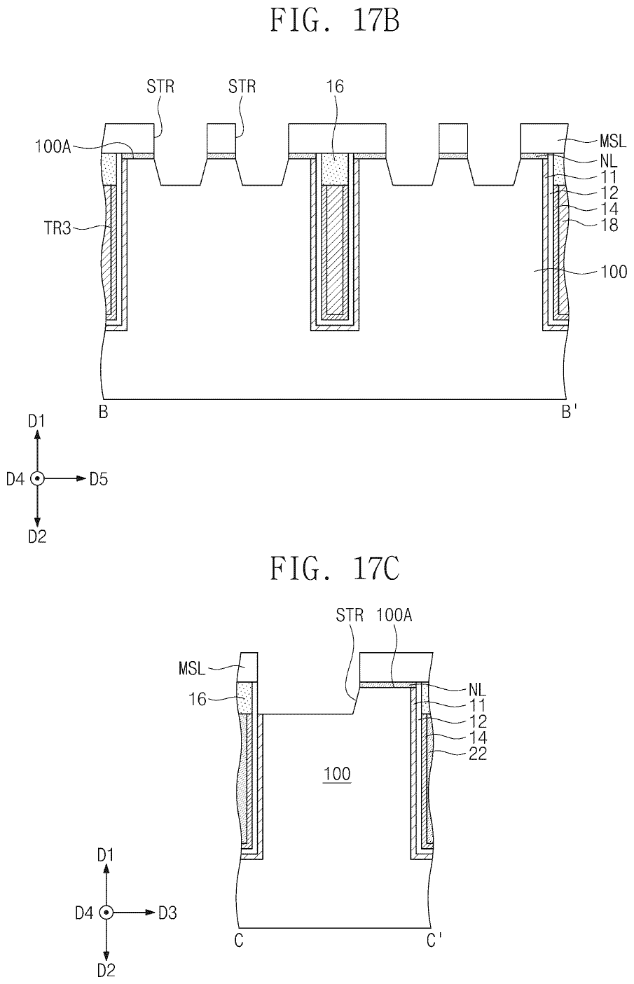

Referring to FIGS. 16A, 16B, and 16C, a planarization process may be performed. Performing the planarization process may include performing a chemical mechanical polishing (CMP) process. Accordingly, the upper portion of the insulating liner layer 12p, the upper portion of the preliminary buried insulating pattern 16p, and the second insulating layer OL may be removed. The upper portion of the insulating liner layer 12p may be removed to form an insulating liner 12. The upper portion of the preliminary buried insulating pattern 16p may be removed to form a buried insulating pattern 16. The second insulating layer OL may be removed to expose an upper portion of the first insulating layer NL.

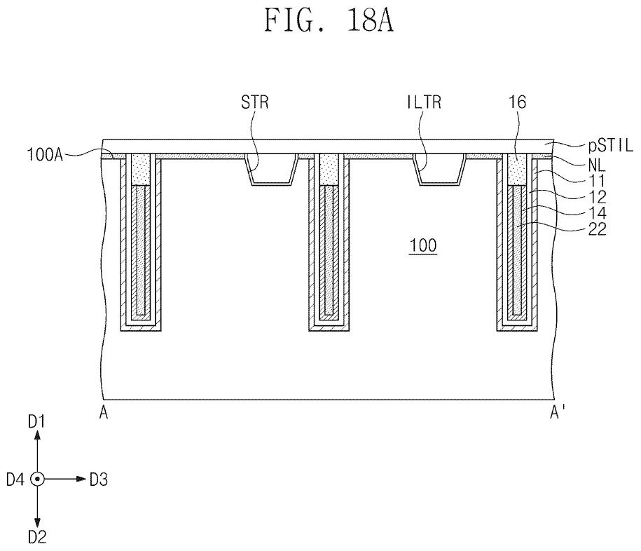

Referring to FIGS. 17A, 17B, and 17C, a mask layer MSL may be formed on the first insulating layer NL. A shallow device isolation trench STR may be formed by using the mask layer MSL as an etch mask to etch the first insulating layer NL and a portion of the substrate 100.

Referring to FIGS. 17A and 17B, the shallow device isolation trench STR may be recessed from the first surface 100A of the substrate 100 into the substrate 100. In some implementations, the shallow device isolation trench STR may be formed to be spaced apart from the previously formed buried insulating pattern 16, insulating liner 12, conductive liner 14, buried conductive layer 18, buried layer 22, and doped region 11.

Referring to FIG. 17C, in some implementations, the shallow device isolation trench STR may be formed to expose the insulating liner 12. In this case, an upper portion of the doped region 11 may be etched. As the shallow device isolation trench STR is formed, the upper surface of the doped region 11 and the sidewall of the insulating liner 12 may be exposed.

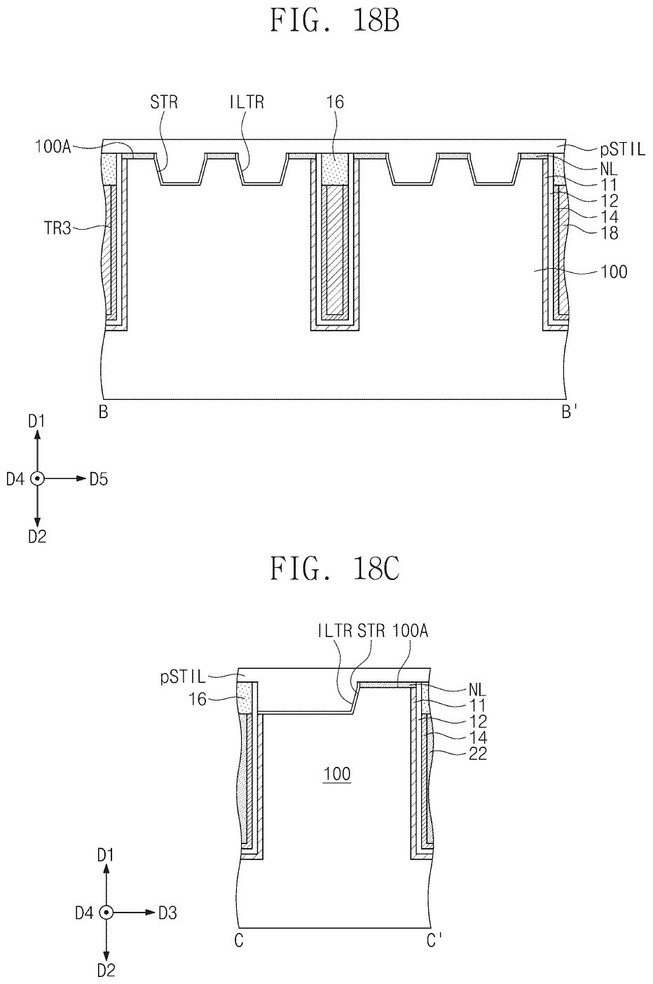

Referring to FIGS. 18A, 18B, and 18C, a first isolation layer 32p may be formed to cover an inner wall of the shallow device isolation trench STR. The first isolation layer 32p may be formed at a level of an upper surface of the first insulating layer NL. The first isolation layer 32p may include the mask pattern remaining after etching to form the shallow device isolation trench STR. The first isolation layer 32p may include oxide and nitride.

A second isolation layer pSTIL may be formed on the first isolation layer 32p. The second isolation layer pSTIL may be formed to fill the remaining region of the device isolation trench STR and cover the first insulating layer NL. Each of the first isolation layer 32p and the second pSTIL may independently include at least one selected from silicon oxide (SiO), silicon nitride (SiN), silicon carbonitride (SiCN), or silicon oxycarbonitride (SiOCN), or a combination thereof.

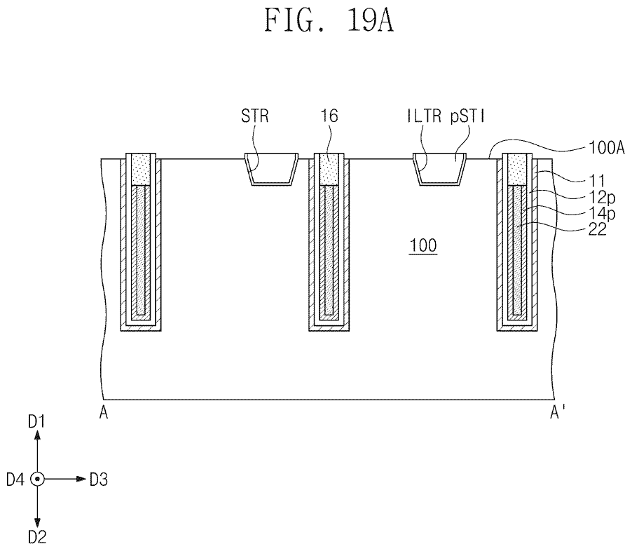

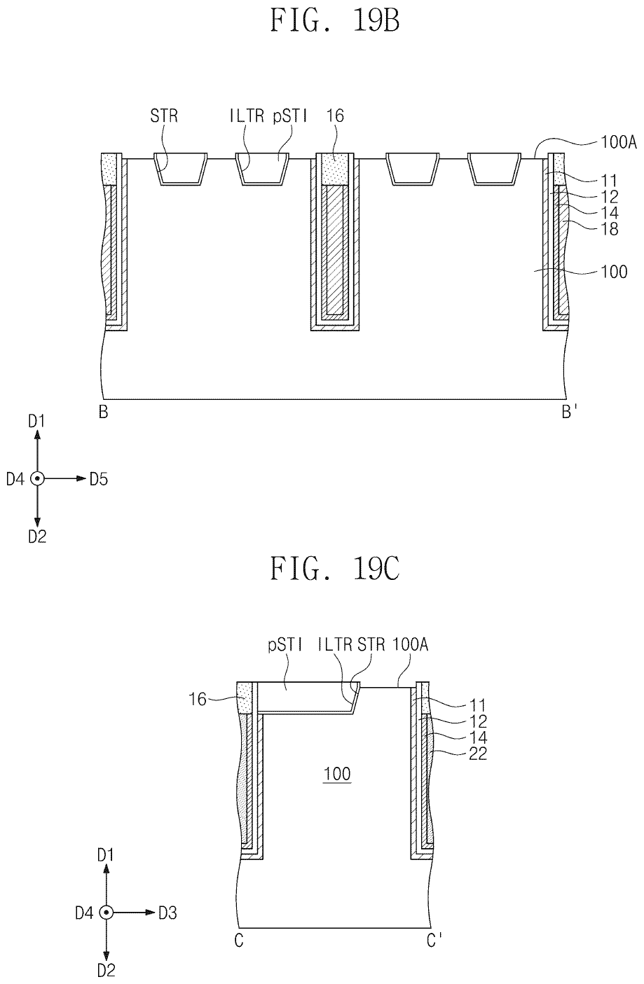

Referring to FIGS. 19A, 19B, and 19C, a planarization process may be performed. Performing the planarization process may include performing a chemical mechanical polishing (CMP) process. Accordingly, a portion of the second isolation layer pSTIL may be removed. The second isolation layer pSTIL at a level above the upper surface of the first insulating layer NL may be removed.

Thereafter, the first insulating layer NL may be removed. Removing the first insulating layer NL may include, for example, a nitride stripping and cleaning process.

Referring again to FIGS. 3 and 4A to 4C, an interlayer dielectric layer ILD, wirings 60 in the interlayer dielectric layer ILD, a gate insulating pattern GI, and a transfer gate TG, may be provided on the first surface 100A of the substrate 100, through a wiring process, a trimming process, and a bonding process.

The substrate 100 may be partially etched at a level of the doped region 11 to define the second surface 100B. An anti-reflective layer 42 may be formed on the second surface 100B of the substrate 100.

Thereafter, light-shielding patterns 48 may be formed on the anti-reflective layer 42, and low refractive patterns 50 may be formed on the light-shielding patterns 48. Color filters CF1 and CF2 may be formed between the low refractive patterns 50. Microlenses ML may be formed on the color filters CF1 and CF2, and the image sensors of FIGS. 3 and 4A to 4C may be formed.

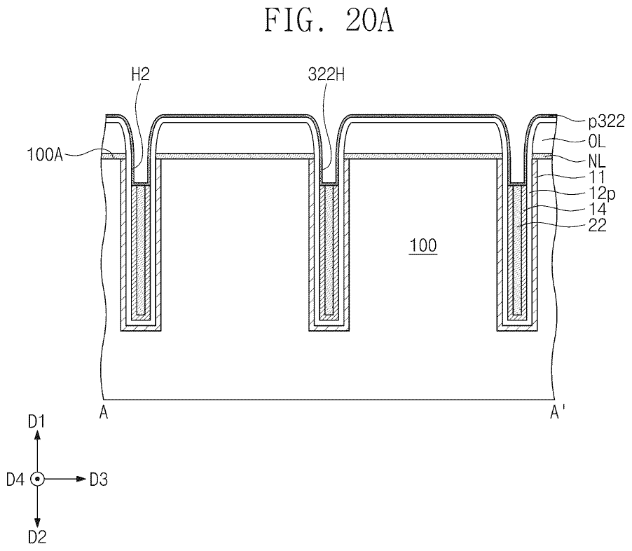

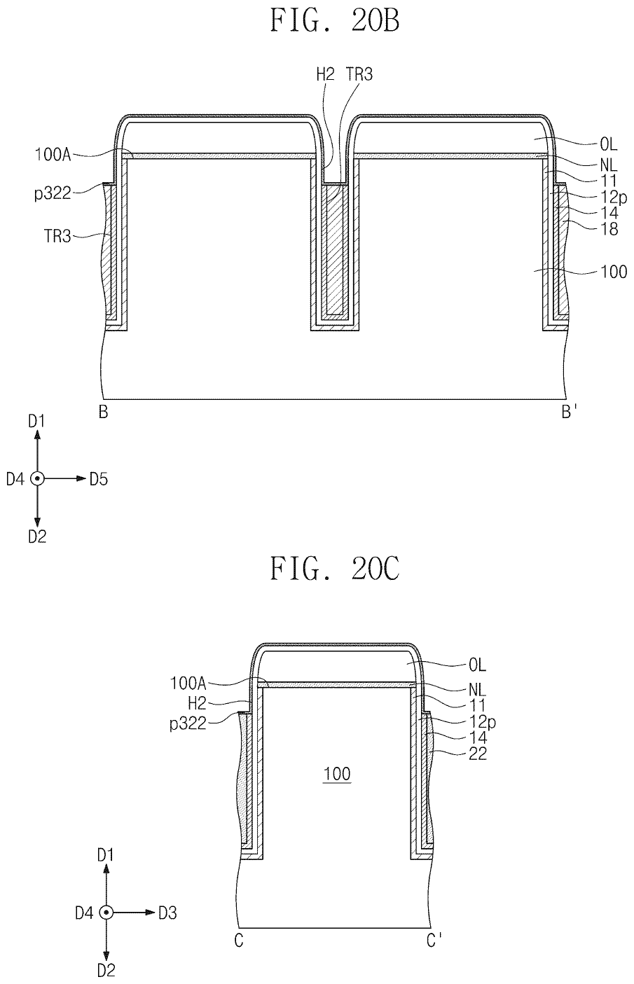

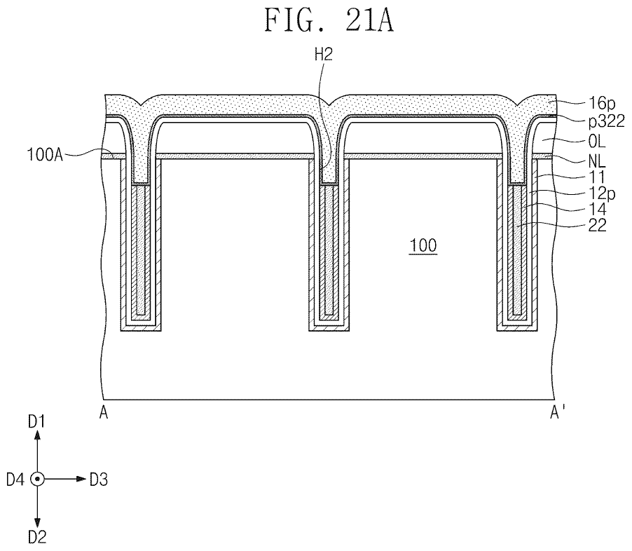

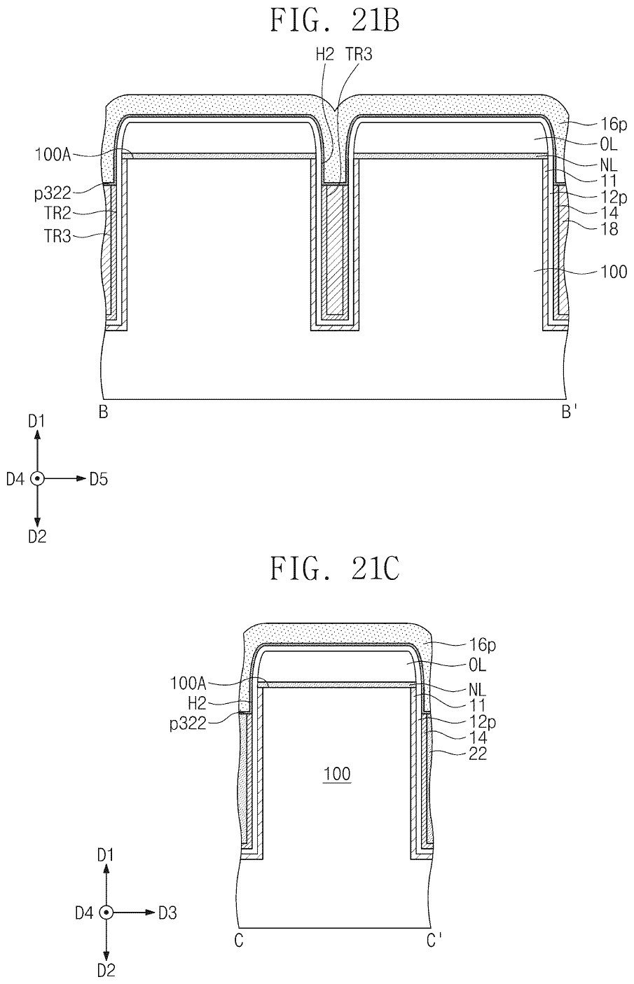

FIGS. 20A to 21C are diagrams illustrating an example of a method of fabricating an image sensor, and are example cross-sectional views corresponding to lines A-A′, B-B′, and C-C′ of FIG. 3. To simplify the explanation, content that overlaps with the above content is omitted.

Referring to FIGS. 20A, 20B, and 20C, a preliminary intervening insulating pattern p322 may be formed after the upper portion of the preliminary buried conductive layer 18p is removed and before the preliminary buried insulating pattern 16p is formed. The preliminary intervening insulating pattern p322 may include, for example, nitride.

Referring to FIGS. 20A and 20C, forming the preliminary interposition insulating pattern p322 between the first pixel PX1 and the second pixel PX2 may include conformally covering an inner wall of the second hole H2, which is formed by removing the upper portion of the preliminary buried conductive layer 18p, with the preliminary interposition insulating pattern p322. The preliminary intervening insulating pattern p322 may be formed to cover the buried layer 22, the upper surface of the conductive liner 14, and the insulating liner layer 12p. An intervening insulating hole 322H may be formed by the preliminary intervening insulating pattern p322. Referring again to FIG. 20B, in a portion surrounded by the first to fourth pixels PX1, PX2, PX3, and PX4, the preliminary intervening insulating pattern p322 may be formed to conformally cover the inner wall of the second hole H2. The preliminary intervening insulating pattern p322 may be formed to cover the upper surface of the buried conductive layer 18, the upper surface of the conductive liner 14, and the insulating liner layer 12p. The intervening insulating hole 322H may be formed by the preliminary intervening insulating pattern p322.

Referring to FIGS. 21A, 21B, and 21C, a preliminary buried insulating pattern 16p may be formed on the preliminary intervening insulating pattern p322 to fill the intervening insulating hole p322H.

Thereafter, an image sensor may be fabricated through a process similar to the process shown in FIGS. 16A to 16C below.

In some implementations, the image sensor may have the deep isolation pattern and the shallow device isolation pattern that define the pixel region. In this case, the active region of the image sensor may be formed as large as the device isolation pattern.

In some implementations, the shallow device isolation pattern may be provided in the pixel region. In this case, the receiving region may be expanded, thereby improving the sensitivity.

In some implementations, the deep isolation pattern may include the conductive liner. Accordingly, the negative bias may be applied to the image sensor.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While implementations are described above, a person skilled in the art may understand that many modifications and variations are made without departing from the spirit and scope of the concept defined in the following claims. Accordingly, the example implementations of the concept should be considered in all respects as illustrative and not restrictive, with the spirit and scope of the concept being indicated by the appended claims.

What is claimed is:

1. An image sensor comprising:
a substrate having a first surface, the substrate including a plurality of pixel regions;
a deep isolation pattern extending from the first surface into the substrate, the deep isolation pattern interposed between the plurality of pixel regions; and
a shallow device isolation pattern extending from the first surface into the substrate,
wherein the deep isolation pattern and the shallow device isolation pattern are spaced apart from each other,
wherein a width of the deep isolation pattern is constant, and
wherein a width of the shallow device isolation pattern decreases as a distance from the first surface increases.

2. The image sensor of claim 1, wherein the shallow device isolation pattern is disposed in a pixel region of the plurality of pixel regions.

3. The image sensor of claim 1, wherein the deep isolation pattern includes:
a buried insulating pattern contacting the first surface,
a buried layer on the buried insulation pattern,
a conductive liner on the buried layer, and
an insulating liner on the conductive liner, and
wherein an upper surface of the buried insulating pattern contacts the conductive liner and the buried layer.

4. The image sensor of claim 3, wherein the deep isolation pattern includes a doped region on the insulating liner, and
wherein the doped region includes boron.

5. The image sensor of claim 3, wherein the deep isolation pattern includes an intervening insulating pattern surrounding the buried insulating pattern, and
wherein the intervening insulating pattern is disposed between the insulating liner and the buried insulating pattern, between the buried layer and the buried insulating pattern, and between the conductive liner and the buried insulating pattern.

6. The image sensor of claim 5, wherein the intervening insulating pattern includes nitride.

7. The image sensor of claim 3, wherein the buried insulating pattern includes oxide.

8. The image sensor of claim 3, wherein a distance from the first surface to an upper surface of the buried insulating pattern is 500 to 4000 Å.

9. An image sensor comprising:
a substrate having a first surface, the substrate including a plurality of pixel regions;
a deep isolation pattern extending from the first surface into the substrate, the deep isolation pattern interposed between the plurality of pixel regions; and
a shallow device isolation pattern extending from the first surface into the substrate,
wherein the deep isolation pattern includes:
a buried insulating pattern contacting the first surface;
an intervening insulating pattern on the buried insulating pattern;
a buried layer on the intervening insulating pattern;
a conductive liner on the buried layer;
an insulating liner on the conductive liner; and
a doped region on the insulating liner, and
wherein the intervening insulating pattern surrounds side and upper surfaces of the buried insulating pattern, and the intervening insulating pattern is interposed between the buried insulating pattern and the buried layer.

10. The image sensor of claim 9, wherein the deep isolation pattern and the shallow device isolation pattern are spaced apart from each other,
wherein the deep isolation pattern is disposed between the plurality of pixel regions, and
wherein the shallow device isolation pattern is disposed in a pixel region of the plurality of pixel regions.

11. The image sensor of claim 9, wherein a first sidewall of the deep isolation pattern contacts the shallow device isolation pattern, and
wherein a second sidewall of the deep isolation pattern is spaced apart from the shallow device isolation pattern.

12. The image sensor of claim 9, wherein the buried layer includes polysilicon or SiO₂, and
wherein the conductive liner includes boron-doped silicon.

13. The image sensor of claim 9, wherein a width of the deep isolation pattern is constant, and
wherein a width of the shallow device isolation pattern decreases as a distance from the first surface increases.

14. The image sensor of claim 9, wherein the intervening insulating pattern includes nitride.

15. The image sensor of claim 9, comprising a transfer gate disposed on the first surface of the substrate,
wherein the transfer gate extends into the substrate.

16. The image sensor of claim 9, wherein an inner wall of the interposed insulating pattern contacts the buried insulating pattern, and
wherein an outer wall of the intervening insulating pattern contacts the insulating liner.

17. An image sensor comprising:
a substrate having a first surface and a second surface, the substrate including a plurality of pixel regions;
a plurality of microlenses on the second surface of the substrate;
a transfer gate disposed on the first surface of the substrate;
a deep isolation pattern extending from the first surface into the substrate, the deep isolation pattern interposed between the plurality of pixel regions;
an anti-reflective layer on the deep isolation pattern; and
a shallow device isolation pattern extending from the first surface into the substrate,
wherein the shallow device isolation pattern is spaced apart from the deep isolation pattern,
wherein the deep isolation pattern includes:
a buried insulating pattern contacting the first surface;
an intervening insulating pattern on the buried insulating pattern;
a buried layer on the intervening insulating pattern;
a conductive liner on the buried layer;
an insulating liner on the conductive liner; and
a doped region on the insulating liner, and
wherein the intervening insulating pattern surrounds side and upper surfaces of the buried insulating pattern, and the intervening insulating pattern is interposed between the buried insulating pattern and the buried layer.

18. The image sensor of claim 17, wherein the intervening insulating pattern includes nitride.

19. The image sensor of claim 17, wherein the shallow device isolation pattern is disposed in a pixel region of the plurality of pixel regions.

20. The image sensor of claim 17, wherein an inner wall of the interposed insulating pattern contacts the buried insulating pattern, and
wherein an outer wall of the intervening insulating pattern contacts the insulating liner.
